(19) United States
(12) Patent Application Publication
(10) Pub. No.: US 2025/0234735 A1
(43) Pub. Date: Jul. 17, 2025

(54) DISPLAY DEVICE

(71) Applicant: Sharp Display Technology Corporation, Kameyama City, Mie (JP)

(72) Inventors: Tadayoshi MIYAMOTO, Kameyama City, Mie (JP); Yoshinobu NAKAMURA, Kameyama City, Mie (JP)

(21) Appl. No.: 18/702,242

(22) PCT Filed: Dec. 17, 2021
(86) PCT No.: PCT/JP2021/046821

§ 371 Date: Apr. 17, 2024

(51) Int. Cl. H10K 59/131; H10D 86/40; H10D 86/60; H10K 59/80

(52) U.S. Cl. CPC H10K 59/1315; H10D 86/423; H10D 86/443; H10D 86/60; H10K 59/871

(57) ABSTRACT

In a thin film transistor layer, a first semiconductor film made of an oxide semiconductor, a first gate insulating film made of an inorganic insulating film, a first metal film, a first interlayer insulating film made of an inorganic insulating film, a second metal film, a protective insulating film made of an inorganic insulating film, and a flattening film made of an organic resin material are sequentially layered. The protective insulating film includes a thin film portion provided at a portion where a plurality of first wiring lines formed of the first metal film and a plurality of second wiring lines formed of the second metal film intersect with each other so as to be thinner than a portion of the protective insulating film around the intersecting portion.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. In the organic EL display device, a thin film transistor (hereinafter also referred to as “TFT”) is provided for each subpixel being the smallest unit of an image. Well known examples of a semiconductor layer constituting the TFT include a semiconductor layer made of polysilicon having high mobility, and a semiconductor layer made of an oxide semiconductor with a low leakage current such as In—Ga—Zn—O.

For example, PTL 1 exemplifies an organic EL display device as a display device using a TFT substrate including a TFT having an oxide semiconductor layer.

### CITATION LIST

### Patent Literature

PTL 1: JP 6311900 B

### SUMMARY

### Technical Problem

Meanwhile, in a high-resolution display device including a TFT including a semiconductor layer made of an oxide semiconductor, it has been proposed to increase an aperture ratio of a subpixel by reducing a width of a wiring line and thickening the wiring line in order to suppress an increase in wiring line resistance due to the reduced width. When the wiring line becomes thick, the unevenness of the surface becomes large at the intersection of the wiring lines, and thus a flattening film made of an organic resin material provided to eliminate the unevenness becomes thick. In this case, the hydrogen contained in the flattening film is likely to adversely affect the TFT using the oxide semiconductor, and thus the characteristics of the TFT may be deteriorated.

The disclosure has been made in view of this, and an object of the disclosure is to suppress deterioration in characteristics of the thin film transistor using the oxide semiconductor caused by the flattening film.

### Solution to Problem

In order to achieve the object, according to an aspect of the disclosure, there is provided a display device including: a base substrate; a thin film transistor layer which is provided on the base substrate and in which a first semiconductor film made of an oxide semiconductor, a first gate insulating film made of an inorganic insulating film, a first metal film, a first interlayer insulating film made of an inorganic insulating film, a second metal film, a protective insulating film made of an inorganic insulating film, and a flattening film made of an organic resin material are sequentially layered, the thin film transistor layer including a plurality of first wiring lines formed of the first metal film, the plurality of first wiring lines extending in parallel with each other, a plurality of second wiring lines formed of the second metal film, the plurality of second wiring lines extending in parallel with each other in a direction intersecting with the plurality of first wiring lines, and a plurality of first thin film transistors provided corresponding to a plurality of subpixels constituting a display region, and each of the plurality of first thin film transistors including a first semiconductor layer formed of the first semiconductor film, wherein the protective insulating film includes a thin film portion provided at a portion where the plurality of first wiring lines and the plurality of second wiring lines intersect with each other, and being thinner than a portion of the protective insulating film around the portion of intersection.

### Advantageous Effects of Disclosure

According to the disclosure, it is possible to suppress deterioration in characteristics of a thin film transistor using an oxide semiconductor due to a flattening film.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the organic EL display device according to the first embodiment of the disclosure.

FIG. 4 is an equivalent circuit diagram of a TFT layer constituting the organic EL display device according to the first embodiment of the disclosure.

FIG. 5 is a cross-sectional view of an organic EL layer constituting the organic EL display device according to the first embodiment of the disclosure.

FIG. 6 is a cross-sectional view of a main portion of a wiring line intersection portion of the TFT layer constituting the organic EL display device according to the first embodiment of the disclosure.

FIG. 7 is a cross-sectional view of a main portion of an anode electrode contact portion of the TFT layer constituting the organic EL display device according to the first embodiment of the disclosure.

FIG. 8 is a cross-sectional view of a main portion of a wiring line intersection portion of a TFT layer constituting an organic EL display device according to a second embodiment of the disclosure, where FIG. 8 is a view corresponding to FIG. 6.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

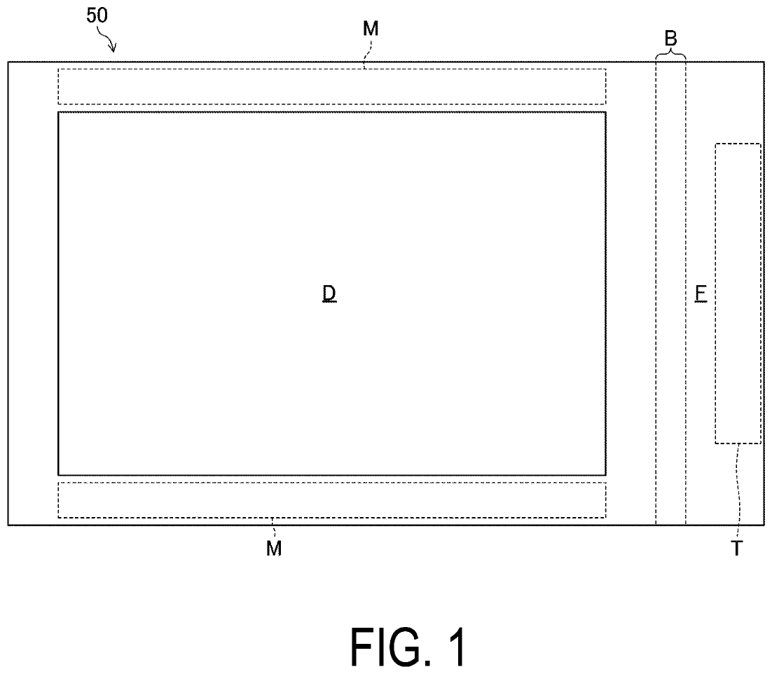

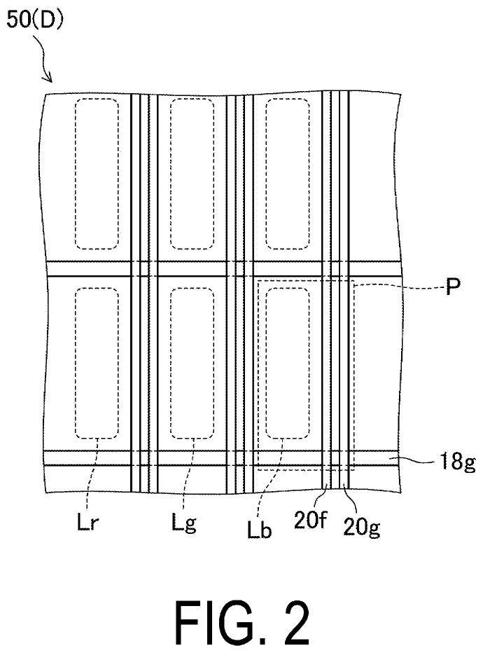

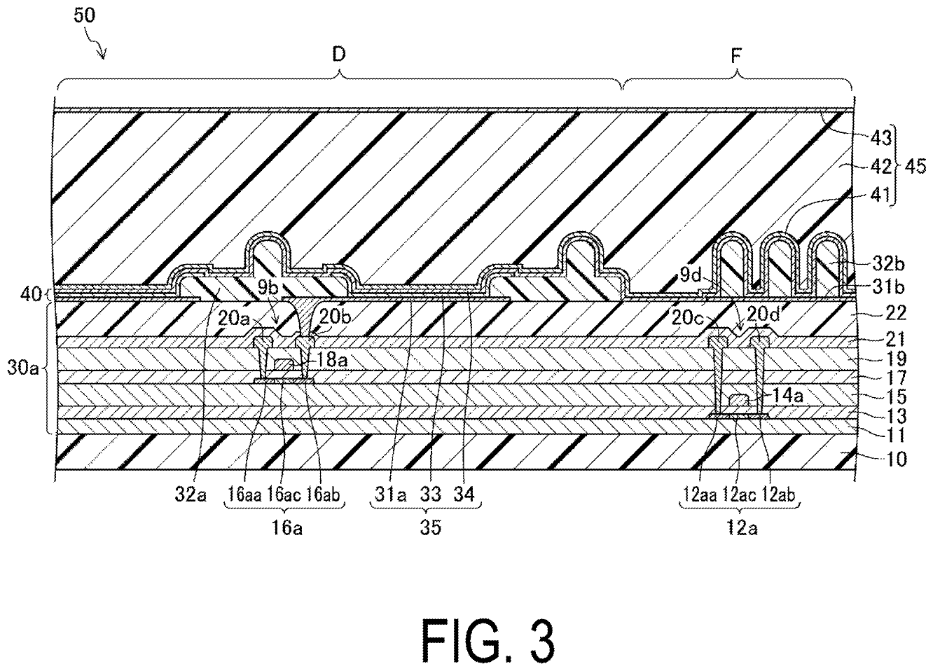

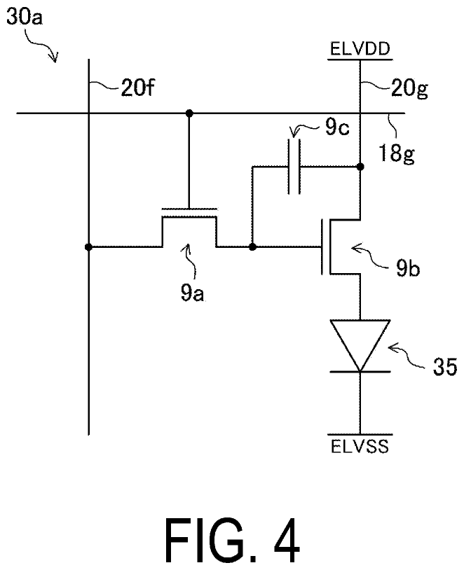

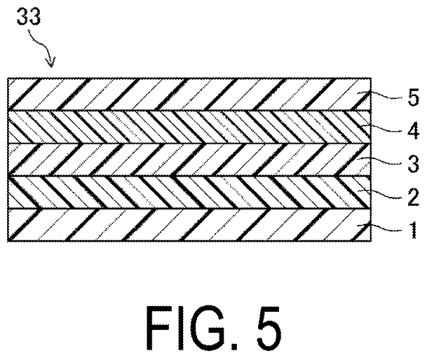

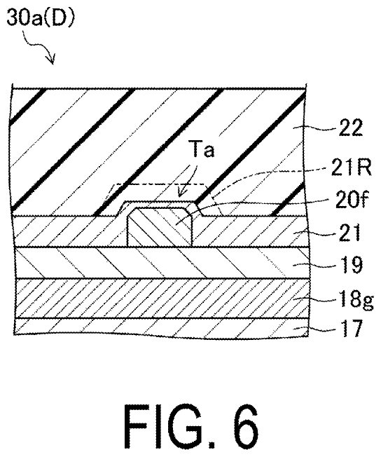

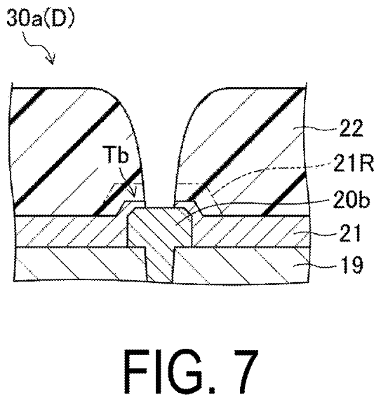

FIG. 1 to FIG. 7 illustrate a display device according to a first embodiment of the disclosure. Note that, in each of the following embodiments, an organic EL display device including an organic EL element layer is exemplified as a display device including a light-emitting element layer. Here, FIG. 1 is a plan view illustrating a schematic configuration of an organic EL display device 50 according to the present embodiment. In addition, FIG. 2 is a plan view of a display region D of the organic EL display device 50. FIG. 3 is a cross-sectional view of the organic EL display device 50. FIG. 4 is an equivalent circuit diagram of a TFT layer 30a constituting the organic EL display device 50. FIG. 5 is a cross-sectional view of an organic EL layer 33 constituting the organic EL display device 50. FIG. 6 is a cross-sectional view of a main portion of a wiring line intersection portion of the TFT layer 30a. FIG. 7 is a cross-sectional view of a main portion of an anode electrode contact portion of the TFT layer 30a.

As illustrated in FIG. 1, the organic EL display device 50 includes, for example, the display region D that is provided in a rectangular shape and displays an image, and a frame region F provided in a frame-like shape in a periphery of the display region D. Note that in the present embodiment, the display region D having the rectangular shape is exemplified, but the rectangular shape includes a substantial rectangular shape such as a shape whose sides are arc-shaped, a shape whose corners are arc-shaped, and a shape in which a part of a side has a cutout.

As illustrated in FIG. 2, a plurality of subpixels P are arrayed in a matrix in the display region D. In addition, in the display region D, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another, as illustrated in FIG. 2. Note that one pixel is configured by, for example, three adjacent subpixels P including the red light-emitting region Lr, the green light-emitting region Lg, and the blue light-emitting region Lb in the display region D.

A terminal portion T is provided at a right end portion of the frame region F in FIG. 1 so as to extend in one direction (the vertical direction in the drawing). In addition, between the display region D and the terminal portion T, as illustrated in FIG. 1, that is, in the frame region F, a bending portion B bendable by, for example, 180 degrees (in a U-shape) with the vertical direction in the drawing as a bending axis is provided on the display region D side of the terminal portion T, extending in one direction (vertical direction in the drawing). A drive circuit M is provided as a peripheral circuit at the upper end portion and the lower end portion of the frame region F in FIG. 1.

As illustrated in FIG. 3, the organic EL display device 50 includes a resin substrate 10 provided as a base substrate, the TFT layer 30a provided on the resin substrate 10, an organic EL element layer 40 provided as a light-emitting element layer on the TFT layer 30a, and a sealing film 45 provided to cover the organic EL element layer 40.

The resin substrate 10 is formed of, for example, a polyimide resin.

As illustrated in FIG. 3, the TFT layer 30a includes a base coat film 11 provided on the resin substrate 10, a plurality of first in-pixel TFTs 9a (see FIG. 4), a plurality of second in-pixel TFTs 9b, a plurality of capacitors 9c (see FIG. 4) and a plurality of out-pixel TFTs 9d which are provided on the base coat film 11, and a protective insulating film 21 and a flattening film 22 provided sequentially on each first in-pixel TFT 9a, each second in-pixel TFT 9b, each capacitor 9c and each out-pixel TFT 9d. Here, as illustrated in FIG. 2 and FIG. 4, in the TFT layer 30a, a plurality of gate lines 18g are provided as the first wiring line so as to extend parallel to each other in a lateral direction in the drawings. In the TFT layer 30a, as illustrated in FIG. 2 and FIG. 4, a plurality of the source lines 20f are provided as a second wiring line in such a manner as to extend in a direction intersecting (orthogonal to) the plurality of gate lines 18g, that is, parallel to each other in a longitudinal direction in the drawings. In the TFT layer 30a, as illustrated in FIG. 2 and FIG. 4, a plurality of power source lines 20g are provided as the second wiring line in such a manner as to extend parallel to each other in the longitudinal direction in the drawings. As illustrated in FIG. 2, each power source line 20g is provided to be adjacent to each source line 20f. As illustrated in FIG. 4, in the TFT layer 30a, each subpixel P includes the first in-pixel TFT 9a, the second in-pixel TFT 9b, and the capacitor 9c. Note that, as illustrated in FIG. 3, in the TFT layer 30a, the base coat film 11, a second semiconductor film serving as a second semiconductor layer 12a described later, a second gate insulating film 13, a third metal film serving as a second gate electrode 14a described later, a second interlayer insulating film 15, a first semiconductor film serving as a first semiconductor layer 16a described later, a first gate insulating film 17, a first metal film serving as the gate line 18g, a first interlayer insulating film 19, a second metal film serving as the source line 20f, the protective insulating film 21, and the flattening film 22 are sequentially layered on the resin substrate 10.

Each of the base coat film 11, the second gate insulating film 13, the second interlayer insulating film 15, the first gate insulating film 17, the first interlayer insulating film 19 and the protective insulating film 21 is composed of, for example, a single-layer film or a layered film of an inorganic insulating film such as silicon nitride, silicon oxide, or silicon oxynitride. Here, at least the second interlayer insulating film 15 and the first gate insulating film 17 on sides of the first semiconductor layer 16a are composed of silicon oxide films. Here, as illustrated in FIG. 6, the protective insulating film 21 includes a thin film portion Ta provided at a portion where the plurality of gate lines 18g and the plurality of source lines 20f (and the plurality of power source lines 20g) intersect with each other so as to be thinner (for example, approximately as thick as 50 nm) than a portion of the protective insulating film 21 around the intersecting portion (for example, approximately as thick as 250 nm). A chain double-dashed line 21R in FIG. 6 indicates the surface of the protective insulating film 21 when the protective insulating film 21 is not etched back in the TFT layer forming step of the manufacturing method described later.

As illustrated in FIG. 4, the first in-pixel TFT 9a is electrically connected to the corresponding gate line 18g and source line 20f in each subpixel P. Similar to the second in-pixel TFT 9b described later, the first in-pixel TFT 9a includes the first semiconductor layer (16a), a gate electrode (18a), a first source electrode (20a), and a first drain electrode (20b), and is provided as a first TFT.

As illustrated in FIG. 4, the second in-pixel TFT 9b is electrically connected to the corresponding first in-pixel TFT 9a and the power source line 20g in each subpixel P. As illustrated in FIG. 3, the second in-pixel TFT 9b includes the first semiconductor layer 16a provided on the second interlayer insulating film 15, a first gate electrode 18a provided on the first semiconductor layer 16a with the first gate insulating film 17 interposed therebetween, and a first source electrode 20a and a first drain electrode 20b provided to be separated from each other on the first interlayer insulating film 19, and is provided as a first TFT.

The first semiconductor layer 16a is formed of, for example, an In—Ga—Zn—O based oxide semiconductor, and includes, as illustrated in FIG. 3, a first source region 16aa and a first drain region 16ab defined to be separated from each other, and a first channel region 16ac defined between the first source region 16aa and the first drain region 16ab. Here, the In—Ga—Zn—O based semiconductor is ternary oxide of indium (In), gallium (Ga) and zinc (Zn), and a ratio (composition ratio) of In, Ga, and Zn is not limited to any specific value. The In—Ga—Zn—O based semiconductor may be an amorphous semiconductor or may be a crystalline semiconductor. Note that a crystalline In—Ga—Zn—O based semiconductor in which a c-axis is oriented substantially perpendicular to a layer surface is preferable as the crystalline In—Ga—Zn—O based semiconductor. In place of the In—Ga—Zn—O based semiconductor, another oxide semiconductor may be included. Examples of other oxide semiconductors may include an In—Sn—Zn—O based semiconductor (for example, In₂O₃—SnO₂—ZnO; InSnZnO). The In—Sn—Zn—O based semiconductor is ternary oxide of indium (In), tin (Sn), and zinc (Zn). Alternatively, examples of other oxide semiconductors may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (MgₓZn₁₋ₓO), and cadmium zinc oxide (CdₓZn₁₋ₓO). Note that as the Zn—O based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a polycrystalline state, or a microcrystalline state in which the non-crystalline state and the polycrystalline state are mixed, or a semiconductor to which no impurity element is added can be used.

As illustrated in FIG. 3, the first gate electrode 18a is provided to overlap the first channel region 16ac of the first semiconductor layer 16a, and is configured to control conduction between the first source region 16aa and the first drain region 16ab of the first semiconductor layer 16a. The first gate electrode 18a is formed of the first metal film similarly to the gate line 18g.

As illustrated in FIG. 3, the first source electrode 20a and the first drain electrode 20b are respectively electrically connected to the first source region 16aa and the first drain region 16ab of the first semiconductor layer 16a via contact holes formed in the first gate insulating film 17 and the first interlayer insulating film 19. The first source electrode 20a and the first drain electrode 20b are formed of the second metal film similarly to the source line 20f and the power source line 20g. As illustrated in FIG. 3, the first drain electrode 20b of the second in-pixel TFT 9b is electrically connected to a first electrode 31a via contact holes formed in the protective insulating film 21 and the flattening film 22 as described later. Here, as illustrated in FIG. 7, the protective insulating film 21 includes a thin film portion Tb provided at a portion connecting the first drain electrode 20b and the first electrode 31a in each subpixel P so as to be thinner (for example, approximately as thick as 50 nm) than a portion of the protective insulating film 21 around the connecting portion (for example, approximately as thick as 250 nm). Note that a chain double-dashed line 21R in FIG. 7 indicates the surface of the protective insulating film 21 when the protective insulating film 21 is not etched back in the TFT layer forming step of the manufacturing method described later.

The capacitor 9c is electrically connected to the corresponding first in-pixel TFT 9a and power source line 20g in each subpixel P, as illustrated in FIG. 4. Here, the capacitor 9c includes, for example, a lower conductive layer formed of the first metal film, an upper conductive layer formed of the second metal film, and the first interlayer insulating film 19 provided between the lower conductive layer and the upper conductive layer. Note that the upper conductive layer is electrically connected to the power source line 20g via the contact hole formed in the first interlayer insulating film 19.

The flattening film 22 includes a flat surface in the display region D, and is formed of an organic resin material or the like such as a polyimide resin, for example.

As illustrated in FIG. 3, the organic EL element layer 40 includes a plurality of first electrodes 31a, a common edge cover 32a, a plurality of organic EL layers 33, and a common second electrode 34, which are sequentially layered corresponding to the plurality of subpixels P. Here, in each subpixel P, the first electrode 31a, the organic EL layer 33, and the second electrode 34 constitute an organic EL element 35 (see FIG. 4), as illustrated in FIG. 3.

As illustrated in FIG. 3, the first electrode 31a is electrically connected to the first drain electrode 20b of the second in-pixel TFT 9b of each subpixel P via the contact holes formed in the protective insulating film 21 and the flattening film 22. Additionally, the first electrode 31a has a function to inject a hole (positive hole) into the organic EL layer 33. Additionally, the first electrode 31a is preferably formed of a material having a high work function to improve hole injection efficiency into the organic EL layer 33. Here, examples of a material constituting the first electrode 31a include a metal material such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the material of the first electrode 31a may also include an alloy such as astatine (At)/astatine oxide (AtO₂). Further, the material constituting the first electrode 31a may be, for example, an electrically conductive oxide such as tin oxide (SnO), zinc oxide (ZnO), indium tin oxide (ITO), and indium zinc oxide (IZO). Additionally, the first electrode 31a may be formed by layering a plurality of layers including any of the materials described above. Note that examples of compound materials having a high work function include indium tin oxide (ITO) and indium zinc oxide (IZO).

The edge cover 32a is formed of, for example, an organic resin material such as a polyimide resin or an acrylic resin, or a polysiloxane-based spin-on-glass (SOG) material. Here, as illustrated in FIG. 3, a portion of the surface of the edge cover 32a protrudes upward in the drawing to serve as a pixel photo spacer provided in an island shape.

The organic EL layer 33 is provided as a light-emitting function layer and includes a hole injection layer 1, a hole transport layer 2, a light-emitting layer 3, an electron transport layer 4, and an electron injection layer 5 that are sequentially layered on the first electrode 31a, as illustrated in FIG. 5.

The hole injection layer 1 is also referred to as an anode electrode buffer layer, and has a function to reduce an energy level difference between the first electrode 31a and the organic EL layer 33 and to improve hole injection efficiency from the first electrode 31a into the organic EL layer 33. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function to improve hole transport efficiency from the first electrode 31a to the organic EL layer 33. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where, when a voltage is applied by the first electrode 31a and the second electrode 34, a positive hole and an electron are injected from the first electrode 31a and the second electrode 34, respectively, and the positive hole and the electron are recombined. Here, the light-emitting layer 3 is formed of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 functions to reduce an energy level difference between the second electrode 34 and the organic EL layer 33 to thereby improve the efficiency of electron injection into the organic EL layer 33 from the second electrode 34, and this function allows the drive voltage of the organic EL element 35 to be reduced. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 34 is provided in common to all the subpixels P to cover each organic EL layer 33 and the edge cover 32a. Further, the second electrode 34 functions to inject electrons into the organic EL layer 33. Further, the second electrode 34 is preferably formed of a material having a low work function to improve the efficiency of electron injection into the organic EL layer 33. Here, examples of a material constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed of alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al). Further, the second electrode 34 may be formed of an electrically conductive oxide such as tin oxide (SnO), zinc oxide (ZnO), indium tin oxide (ITO), and indium zinc oxide (IZO). Further, the second electrode 34 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 3, the sealing film 45 is provided to cover the second electrode 34, includes a first inorganic sealing film 41, an organic sealing film 42, and a second inorganic sealing film 43 sequentially layered on the second electrode 34, and has a function to protect the organic EL layer 33 of the organic EL element 35 from moisture, oxygen, and the like. Here, the first inorganic sealing film 41 and the second inorganic sealing film 43 include, for example, an inorganic insulating film such as a silicon nitride film, a silicon oxide film, and a silicon oxynitride film. Additionally, the organic sealing film 42 is made of, for example, an organic resin material such as an acrylic resin, an epoxy resin, a silicone resin, a polyurea resin, a parylene resin, a polyimide resin, and a polyamide resin.

As illustrated in FIG. 3, the organic EL display device 50 includes a plurality of peripheral photo spacers 32b provided in island shapes on the flattening film 22 in the frame region F so as to protrude upward in the drawing with a conductive layer 31b interposed therebetween. Here, each peripheral photo spacer 32b is formed of the same material as the edge cover 32a in the same layer. The conductive layer 31b is formed of the same material as the first electrode 31a in the same layer.

As illustrated in FIG. 3, the organic EL display device 50 includes the plurality of out-pixel TFTs 9d provided as second TFTs constituting the drive circuit M in the frame region F.

As illustrated in FIG. 3, the out-pixel TFT 9d includes the second semiconductor layer 12a provided on the base coat film 11, the second gate electrode 14a provided on the second semiconductor layer 12a with the second gate insulating film 13 interposed therebetween, and a second source electrode 20c and a second drain electrode 20d provided on the first interlayer insulating film 19 so as to be separated from each other.

The second semiconductor layer 12a is formed of, for example, polysilicon such as low temperature polysilicon (LTPS), and as illustrated in FIG. 3, includes a second source region 12aa and a second drain region 12ab defined to be separated from each other, and a second channel region 12ac defined between the second source region 12aa and the second drain region 12ab.

As illustrated in FIG. 3, the second gate electrode 14a is provided so as to overlap the second channel region 12ac of the second semiconductor layer 12a, and is configured to control conduction between the second source region 12aa and the second drain region 12ab of the second semiconductor layer 12a. The second gate electrode 14a is formed of the third metal film.

As illustrated in FIG. 3, the second source electrode 20c and the second drain electrode 20d are respectively electrically connected to the second source region 12aa and the second drain region 12ab of the second semiconductor layer 12a via contact holes formed in the second gate insulating film 13, the second interlayer insulating film 15, the first gate insulating film 17, and the first interlayer insulating film 19. The second source electrode 20c and the second drain electrode 20d are formed of the second metal film similarly to the source line 20f, the power source line 20g, the first source electrode 20a, and the first drain electrode 20b.

The organic EL display device 50 includes, in the frame region F, a first dam wall provided in a frame-like shape so as to surround the display region D and a second dam wall provided in a frame-like shape around the first dam wall. Here, the first dam wall and the second dam wall each include, for example, a lower resin layer formed of the same material and in the same layer as those of the flattening film 22, and an upper resin layer provided on the lower resin layer and formed of the same material and in the same layer as those of the edge cover 32a. Note that the first dam wall is provided overlapping an outer peripheral edge portion of the organic sealing film 42 of the sealing film 45, and is configured to suppress the spread of ink corresponding to the organic sealing film 42.

In the organic EL display device 50 described above, in each subpixel P, a gate signal is input to the first in-pixel TFT 9a via the gate line 18g to turn on the first in-pixel TFT 9a, a data signal is written in the first gate electrode 18a of the second in-pixel TFT 9b and the capacitor 9c via the source line 20f, and a current from the power source line 20g corresponding to a gate voltage of the second in-pixel TFT 9b is supplied to the organic EL layer 33, whereby the light-emitting layer 3 of the organic EL layer 33 emits light to display an image. Note that, in the organic EL display device 50, even when the first in-pixel TFT 9a is turned off, the gate voltage of the second in-pixel TFT 9b is held by the capacitor 9c. Thus, the light emission by the light-emitting layer 3 is maintained until a gate signal of the next frame is input.

Next, a method of manufacturing the organic EL display device 50 according to the present embodiment will be described. Here, the method of manufacturing the organic EL display device 50 according to the present embodiment includes a TFT layer forming step, an organic EL element layer forming step, and a sealing film forming step.

### TFT Layer Forming Step

First, a silicon nitride film (having a thickness of about 50 nm) and a silicon oxide film (having a thickness of about 250 nm) are sequentially formed on the resin substrate 10 formed on a glass substrate by, for example, plasma chemical vapor deposition (CVD), to form the base coat film 11.

Subsequently, an amorphous silicon film (having a thickness of approximately 50 nm) is formed on the substrate surface on which the base coat film 11 is formed by plasma CVD, for example, the amorphous silicon film is crystallized by laser annealing or the like to form the second semiconductor film formed of polysilicon, and then the second semiconductor film is patterned to form the second semiconductor layer 12a.

Thereafter, a silicon oxide film (having a thickness of approximately 100 nm) is formed by, for example, plasma CVD, on the substrate surface where the second semiconductor layer 12a is formed, thereby forming the second gate insulating film 13.

Next, a third metal film such as a molybdenum film (having a thickness of about 200 nm) is formed by, for example, the sputtering method on the substrate surface on which the second gate insulating film 13 is formed, and then the third metal film is patterned to form the second gate electrode 14a.

Subsequently, by doping the second semiconductor layer 12a with impurity ions using the second gate electrode 14a as a mask, a part of the second semiconductor layer 12a is made conductive, and the second source region 12aa, the second drain region 12ab, and the second channel region 12ac are formed in the second semiconductor layer 12a.

Thereafter, a silicon nitride film (having a thickness of approximately 150 nm) and a silicon oxide film (having a thickness of approximately 100 nm) are sequentially formed, for example, by plasma CVD, on the substrate surface on which a part of the second semiconductor layer 12a has been made conductive, to form the second interlayer insulating film 15.

Further, on the substrate surface on which the second interlayer insulating film 15 is formed, the first semiconductor film formed of an oxide semiconductor such as an InGaZnO₄ film (having a thickness of about 30 nm) is formed by, for example, sputtering, and then the first semiconductor film is patterned to form the first semiconductor layer 16a.

Subsequently, a silicon oxide film (having a thickness of approximately 100 nm) is formed by, for example, plasma CVD, on the substrate surface where the first semiconductor layer 16a is formed, thereby forming the first gate insulating film 17.

Thereafter, the first metal film such as a molybdenum film (having a thickness of approximately 200 nm) is formed by, for example, the sputtering method on the substrate surface on which the first gate insulating film 17 is formed, and then the first metal film is patterned to form the first gate electrode 18a, the gate line 18g, and the like.

Further, on the substrate surface on which the first gate electrode 18a and the like are formed, a silicon oxide film (having a thickness of about 300 nm) and a silicon nitride film (having a thickness of about 150 nm) are sequentially formed by, for example, plasma CVD, thereby forming the first interlayer insulating film 19. A part of the first semiconductor layer 16a is made conductive by heat treatment after the formation of the first interlayer insulating film 19, so that the first source region 16aa, the first drain region 16ab, and the first channel region 16ac are formed in the first semiconductor layer 16a.

Subsequently, on the substrate surface on which the first interlayer insulating film 19 is formed, the second gate insulating film 13, the second interlayer insulating film 15, the first gate insulating film 17, and the first interlayer insulating film 19 are suitability patterned to form a contact hole.

Thereafter, a titanium film (having a thickness of approximately 50 nm), an aluminum film (having a thickness of approximately 400 nm), a titanium film (having a thickness of approximately 200 nm), and the like are sequentially formed by, for example, the sputtering method on the substrate surface on which the contact hole described above is formed, to form the second metal film, and subsequently the second metal film is patterned to form the first source electrode 20a, the first drain electrode 20b, the second source electrode 20c, the second drain electrode 20d, the source line 20f, the power source line 20g, and the like.

Further, a silicon oxide film (having a thickness of approximately 250 nm) is formed on the substrate surface on which the first source electrode 20a and the like are formed by, for example, plasma CVD, and then the silicon oxide film is patterned (etch-back) to remove the intersection of the gate lines 18g, the source lines 20f, and the power source lines 20g and a portion of the second in-pixel TFT 9b above the first drain electrode 20b by dry etching, thereby forming the protective insulating film 21 including the thin film portions Ta and Tb having a thickness of approximately 50 nm.

Subsequently, an acrylic photosensitive resin film (having a thickness of approximately 2 μm) is applied to the substrate surface on which the protective insulating film 21 is formed by, for example, a spin coating method or a slit coating method, and then pre-baking, exposing, developing, and post-baking are performed on the applied film to form the flattening film 22 including a contact hole.

Finally, the protective insulating film 21 exposed from the contact hole of the flattening film 22 is removed so that the contact hole reaches the second drain electrode 20d of the second in-pixel TFT 9b.

As described above, the TFT layer 30a can be formed.

### Organic EL Element Layer Forming Step

The organic EL element layer 40 is formed by forming the first electrodes 31a, the edge cover 32a, the organic EL layer 33 (the hole injection layer 1, the hole transport layer 2, the light-emitting layer 3, the electron transport layer 4, and the electron injection layer 5), and the second electrode 34 on the flattening film 22 of the TFT layer 30a that has been formed in the TFT layer forming step described above, by using a known method.

### Sealing Film Forming Step

First, an inorganic insulating film such as a silicon nitride film, a silicon oxide film, or a silicon oxynitride film is formed by plasma CVD on a substrate surface formed with the organic EL element layer 40 formed in the organic EL element layer forming step described above by using a mask to form the first inorganic sealing film 41.

Next, on the substrate surface formed with the first inorganic sealing film 41, a film made of an organic resin material such as acrylic resin is formed by, for example, using an ink-jet method to form the organic sealing film 42.

Further, an inorganic insulating film such as a silicon nitride film, a silicon oxide film, or a silicon oxynitride film is formed by plasma CVD on the substrate formed with the organic sealing film 42 by using a mask to form the second inorganic sealing film 43, thereby forming the sealing film 45.

Finally, after a protective sheet (not illustrated) is attached to the substrate surface on which the sealing film 45 is formed, the glass substrate is peeled off from the lower face of the resin substrate 10 by irradiation with laser light from the glass substrate side of the resin substrate 10, and further a protective sheet (not illustrated) is attached to the lower face of the resin substrate 10 from which the glass substrate has been peeled off.

The organic EL display device 50 of the present embodiment can be manufactured in the manner described above.

As described above, according to the organic EL display device 50 of the present embodiment, the protective insulating film 21 includes the thin film portion Ta provided at the portion where the gate lines 18g intersect with the source lines 20f and the power source lines 20g so as to be thinner than the portion of the protective insulating film 21 around the intersecting portion, and thus the unevenness on the surface of the protective insulating film 21 can be reduced. Therefore, the thickness of the flattening film 22 provided on the protective insulating film 21 can be reduced (by approximately from 0.3 μm to 0.5 μm compared to the case where the thin film portion Ta is not provided). Therefore, the amount of hydrogen released from the flattening film 22 can be reduced, and thus it is possible to suppress the deterioration of the characteristics of the first in-pixel TFT 9a and the second in-pixel TFT 9b using an oxide semiconductor due to the flattening film 22. Furthermore, since the thickness of the flattening film 22 can be reduced, the diameter of the contact hole formed in the flattening film 22 can be reduced, and the aperture ratio of the subpixel P can be increased.

According to the organic EL display device 50 of the present embodiment, since the protective insulating film 21 includes the thin film portion Tb provided at a portion of the second in-pixel TFT 9b in each subpixel P where the first drain electrode 20b and the first electrode 31a are connected to each other so as to be thinner than the portion of the protective insulating film 21 around the connecting portion, the hydrogen contained in the titanium layer of the first drain electrode 20b can be easily released from the thin film portion Tb of the protective insulating film 21 to the outside during the heat treatment in the subsequent manufacturing step. Accordingly, the amount of hydrogen released from the first drain electrode 20b can be reduced, and thus it is possible to suppress the deterioration of the characteristics of the second in-pixel TFT 9b using the oxide semiconductor due to the first drain electrode 20b.

### Second Embodiment

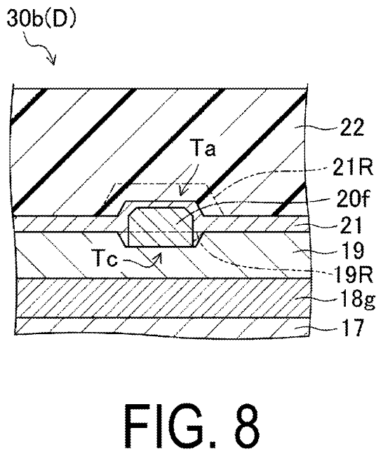

FIG. 8 illustrates a second embodiment of a display device according to the disclosure. Here, FIG. 8 is a cross-sectional view of a main portion of a wiring line intersection portion of a TFT layer 30b constituting an organic EL display device of the present embodiment, where FIG. 8 is a view corresponding to FIG. 6. In the following embodiment, parts identical to those in FIG. 1 to FIG. 7 are designated by the same reference signs, and detailed descriptions thereof will be omitted.

In the first embodiment described above, the organic EL display device 50 including the TFT layer 30a provided with the thin film portions Ta and Tb is illustrated, while in the present embodiment, the organic EL display device including the TFT layer 30b provided with the thin film portions Ta and Tb, and a thin film portion Tc will be illustrated.

Similar to the organic EL display device 50 of the first embodiment described above, the organic EL display device of the present embodiment includes the display region D provided in a rectangular shape and the frame region F provided in a frame-like shape around the display region D.

The organic EL display device of the present embodiment includes the resin substrate 10, the TFT layer 30b provided on the resin substrate 10, the organic EL element layer 40 on the TFT layer 30b, and the sealing film 45 provided to cover the organic EL element layer 40.

Similarly to the TFT layer 30a of the first embodiment described above, the TFT layer 30b includes the base coat film 11 provided on the resin substrate 10, the plurality of first in-pixel TFTs 9a, the plurality of second in-pixel TFTs 9b, the plurality of capacitors 9c and the plurality of out-pixel TFTs 9d which are provided on the base coat film 11, and the protective insulating film 21 and the flattening film 22 provided sequentially on each first in-pixel TFT 9a, each second in-pixel TFT 9b, each capacitor 9c and each out-pixel TFT 9d. Here, similarly to the TFT layer 30a of the first embodiment described above, the plurality of gate lines 18g, the plurality of source lines 20f, and the plurality of power source lines 20g are provided in the TFT layer 30b. In addition, similarly to the TFT layer 30a of the first embodiment described above, in the TFT layer 30b, the first in-pixel TFT 9a, the second in-pixel TFT 9b, and the capacitor 9c are provided in each subpixel P. In the TFT layer 30b, similarly to the TFT layer 30a of the first embodiment described above, the base coat film 11, the second semiconductor film serving as the second semiconductor layer 12a, the second gate insulating film 13, the third metal film serving as the second gate electrode 14a, the second interlayer insulating film 15, the first semiconductor film serving as the first semiconductor layer 16a, the first gate insulating film 17, the first metal film serving as the gate line 18g, the first interlayer insulating film 19, the second metal film serving as the source line 20f, the protective insulating film 21, and the flattening film 22 are sequentially layered on the resin substrate 10.

As illustrated in FIG. 8, the first interlayer insulating film 19 includes the thin film portion Tc provided at a portion where the plurality of gate lines 18g and the plurality of source lines 20f (and the plurality of power source lines 20g) intersect with each other so as to be thinner (for example, approximately as thick as 300 nm) than a portion of the first interlayer insulating film 19 around the intersecting portion (for example, approximately as thick as 450 nm). Similarly to the TFT layer 30a of the first embodiment described above, as illustrated in FIG. 8, the protective insulating film 21 includes the thin film portion Ta provided at a portion where the plurality of gate lines 18g and the plurality of source lines 20f (and the plurality of power source lines 20g) intersect with each other so as to be thinner (for example, approximately as thick as 50 nm) than a portion of the protective insulating film 21 around the intersecting portion (for example, approximately as thick as 250 nm). Chain double-dashed lines 19R and 21R in FIG. 8 indicate the surfaces of the first interlayer insulating film 19 and the protective insulating film 21, respectively, when they are not etched back in the TFT layer forming step. In addition, similarly to the TFT layer 30a of the first embodiment described above, the protective insulating film 21 includes the thin film portion Tb provided at a portion connecting the first drain electrode 20b and the first electrode 31a in each subpixel P so as to be thinner (for example, approximately as thick as 50 nm) than at a portion of the protective insulating film 21 around the connecting portion (for example, approximately as thick as 250 nm).

Similarly to the organic EL display device 50 of the first embodiment described above, the organic EL display device of the present embodiment includes the plurality of peripheral photo spacers 32b, the plurality of out-pixel TFTs 9d, the first dam wall and the second dam wall in the frame region F.

Similarly to the organic EL display device 50 of the first embodiment described above, the organic EL display device including the TFT layer 30b with the configuration described above is flexible and is configured to display an image by causing the light-emitting layer 3 of the organic EL layer 33 to appropriately emit light via the first in-pixel TFT 9a and the second in-pixel TFT 9b in each subpixel P.

The organic EL display device 50 of the present embodiment can be manufactured by forming the first interlayer insulating film 19 in the TFT layer forming step in the manufacturing method of the organic EL display device 50 of the first embodiment described above, and then patterning (etching back) the first interlayer insulating film 19 so as to remove a portion of the first interlayer insulating film 19 where the gate lines 18g is to intersect with the source lines 20f and the power source lines 20g by dry etching.

As described above, according to the organic EL display device of the present embodiment, the first interlayer insulating film 19 and the protective insulating film 21 respectively include the thin film portions Tc and Ta provided at the portion where the gate lines 18g intersect with the source lines 20f and the power source lines 20g so as to be thinner than the portions of the first interlayer insulating film 19 and the protective insulating film 21 around the intersecting portion, respectively, and thus the unevenness on the surface of the protective insulating film 21 can be further reduced. Therefore, the thickness of the flattening film 22 provided on the protective insulating film 21 can be further reduced (by approximately from 0.5 μm to 0.7 μm compared to the case where the thin film portions Tc and Ta are not provided). Therefore, the amount of hydrogen released from the flattening film 22 can be further reduced, and thus it is possible to further suppress the deterioration of the characteristics of the first in-pixel TFT 9a and the second in-pixel TFT 9b using the oxide semiconductor due to the flattening film 22. Furthermore, since the thickness of the flattening film 22 can be further reduced, the diameter of the contact hole formed in the flattening film 22 can be further reduced, and the aperture ratio of the subpixel P can be further increased.

According to the organic EL display device of the present embodiment, since the protective insulating film 21 includes the thin film portion Tb provided at a portion of the second in-pixel TFT 9b in each subpixel P where the first drain electrode 20b and the first electrode 31a are connected to each other so as to be thinner than the portion of the protective insulating film 21 around the connecting portion, the hydrogen contained in the titanium layer of the first drain electrode 20b can be easily released from the thin film portion Tb of the protective insulating film 21 to the outside during the heat treatment in the subsequent manufacturing step. Accordingly, the amount of hydrogen released from the first drain electrode 20b can be reduced, and thus it is possible to suppress the deterioration of the characteristics of the second in-pixel TFT 9b using the oxide semiconductor due to the first drain electrode 20b.

### Other Embodiments

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

Although the organic EL display device in which the electrode of the TFT connected to the first electrode serves as the drain electrode has been exemplified in each of the embodiments described above, the disclosure is also applicable to an organic EL display device in which the electrode of the TFT connected to the first electrode is referred to as the source electrode.

Although in each of the embodiments described above, the top-gate first in-pixel TFT, second in-pixel TFT and out-pixel TFT are exemplified, the first in-pixel TFT, the second in-pixel TFT and the out-pixel TFT may be the bottom-gate TFTs.

Although in each of the embodiments described above, the organic EL display device is exemplified as a display device, the disclosure is also applicable to a liquid crystal display device, and the like. Note that, in the disclosure, the flatness of the flattening film is secured even when it is thin, and thus when the disclosure is applied to a liquid crystal display device, a cell gap of a liquid crystal cell can be easily controlled.

In each of the embodiments described above, the organic EL display device is exemplified as a display device. The disclosure can also be applied to a display device including a plurality of light-emitting elements driven by a current, for example, to a display device including quantum dot light-emitting diodes (QLEDs), which are a light-emitting element using a quantum dot-containing layer.

### Industrial Applicability

As described above, the disclosure is useful for, for example, a high-resolution small-sized display device for a head mounted display (HMD) application or the like.

1. A display device comprising:
a base substrate;
a thin film transistor layer which is provided on the base substrate and in which a first semiconductor film made of an oxide semiconductor, a first gate insulating film made of an inorganic insulating film, a first metal film, a first interlayer insulating film made of an inorganic insulating film, a second metal film, a protective insulating film made of an inorganic insulating film, and a flattening film made of an organic resin material are sequentially layered,
the thin film transistor layer including
a plurality of first wiring lines formed of the first metal film, the plurality of first wiring lines extending in parallel with each other,
a plurality of second wiring lines formed of the second metal film, the plurality of second wiring lines extending in parallel with each other in a direction intersecting with the plurality of first wiring lines, and
a plurality of first thin film transistors provided corresponding to a plurality of subpixels constituting a display region, and
each of the plurality of first thin film transistors including a first semiconductor layer formed of the first semiconductor film,
wherein the protective insulating film includes a thin film portion provided at a portion where the plurality of first wiring lines and the plurality of second wiring lines intersect with each other, and being thinner than a portion of the protective insulating film around the portion of intersection.

2. The display device according to claim 1,
wherein the first interlayer insulating film includes a thin film portion provided at a portion where the plurality of first wiring lines and the plurality of second wiring lines intersect with each other, and being thinner than a portion of the first interlayer insulating film around the portion of intersection.

3. The display device according to claim 2, further comprising
a light-emitting element layer which is provided on the thin film transistor layer and in which a plurality of first electrodes, a plurality of light-emitting function layers, and a common second electrode are sequentially layered corresponding to the plurality of subpixels,
wherein each of the plurality of first thin film transistors includes
the first semiconductor layer in which a first source region and a first drain region are defined to be separated from each other,
a first gate electrode formed of the first metal film on the first semiconductor layer with the first gate insulating film interposed between the first semiconductor layer and the first gate electrode, and
a first source electrode and a first drain electrode, both of which are formed of the second metal film on the first interlayer insulating film, the first source electrode and the first drain electrode being separated from each other and electrically connected to the first source region and the first drain region, respectively, and
the protective insulating film includes a thin film portion provided at a portion connecting the first drain electrode which corresponds and a corresponding first electrode of the plurality of first electrodes in each of the plurality of subpixels, and being thinner than a portion of the protective insulating film around the portion of connection.

4. The display device according to claim 1,
wherein the thin film transistor layer is provided with a second thin film transistor including a second semiconductor layer formed of a second semiconductor film made of polysilicon.

5. The display device according to claim 4,
wherein the thin film transistor layer includes a second gate insulating film made of an inorganic insulating film, a third metal film, a second interlayer insulating film made of an inorganic insulating film, the first semiconductor film, the first gate insulating film, the first metal film, the first interlayer insulating film, the second metal film, the protective insulating film, and the flattening film, all of which are sequentially layered on the second semiconductor film.

6. The display device according to claim 5,
wherein the second thin film transistor includes
the second semiconductor layer in which a second source region and a second drain region are defined to be separated from each other,
a second gate electrode formed of the third metal film on the second semiconductor layer with the second gate insulating film interposed between the second semiconductor layer and the second gate electrode, and
a second source electrode and a second drain electrode, both of which are formed of the second metal film on the first interlayer insulating film, the second source electrode and the second drain electrode being separated from each other and electrically connected to the second source region and the second drain region, respectively.

7. The display device according to claim 4,
wherein the second thin film transistor constitutes a peripheral circuit.

8. The display device according to claim 1,
wherein each of the plurality of first wiring lines is a gate line, and
each of the plurality of second wiring lines is a source line.

9. The display device according to claim 3, further comprising
a sealing film configured to cover the light-emitting element layer.

10. The display device according to claim 3,
wherein each of the plurality of light-emitting function layers is an organic electroluminescence layer.
